(19) United States
(12) Patent Application Publication
(10) Pub. No.: US 2007/0051535 A1
(43) Pub. Date: Mar. 8, 2007

(54) CIRCUIT BOARD ASSEMBLY AND ELECTRONIC DEVICE UTILIZING THE SAME

(75) Inventors: CHIH-CHAN GER, Tu-Cheng,Taipei Hsien (TW); YU-HSIANG LIAO, Tu-Cheng,Taipei Hsien (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/308,935

(22) Filed: May 29, 2006

Related U.S. Application Data
(63) Continuation-in-part of application No. 11/308,052, filed on Mar. 4, 2006.

(30) Foreign Application Priority Data
Sep. 2, 2005 (CN) 200510037027.9

(51) Int. Cl. H05K 1/16

(52) U.S. Cl. 174/260; 174/266

(57) ABSTRACT

An electronic device includes an electronic component (40), a first printed circuit board (PCB) (100) and a second printed circuit board (200). The electronic component includes a first pin (A1) and a second pin (A2). The first PCB and a second PCB, respectively including first conductor trace lines (102) and second conductor trace lines (108) for electrically connecting the first pin and the second pin. The first PCB is disposed above the second PCB, and is parallel with the second PCB. The first PCB is electrically connected to the second PCB via at least one of the first conductor trace lines and the second conductor trace lines. A surface area of the first PCB is smaller than that of the second PCB.

### CROSS-REFERENCE TO RELATED APPLICATIONS

This application is a continuation-in-part of U.S. application Ser. No. 11/308,052, filed on Mar. 4, 2006.

### FIELD OF THE INVENTION

The invention relates to circuit boards, and particularly to circuit board that are integrated together.

### DESCRIPTION OF RELATED ART

Printed circuit boards (PCBs) used in electronic products provide connections among electronic components. With the ongoing development of electronics technology, many electronic components are often required to be disposed on a single PCB. Therefore the circuits disposed on the PCB may be very complex. Nowadays, PCBs are mainly categorized as single-sided boards, double-sided boards, and multi-layer boards. Single-sided boards are the most common kind of PCB in mass-produced consumer electronic products. A single-sided board has all the conductors (copper traces) on one side of the board. Therefore the circuit layout disposed on the single-sided board is restricted, because the traces must not cross each other. Thus, single-sided boards are only suitable for simple circuits. With double-sided boards, the traces can travel from one side of the board to the other through vias. Therefore, double-sided boards are suitable for relatively complex circuits. A multi-layer circuit board is equivalent to an integrated combination of a plurality of single-sided boards and/or double-sided boards. In multi-layer boards, the traces can run on different layers, and use plated through holes or vias to jump from one layer to another. Thus multi-layer boards are used for complex circuits, and are applied as motherboards in computers for example.

Even though multi-layer boards enable construction of circuits of greater complexity and density, they are not always used. This is because of the greater cost of manufacture, and the near impossibility of inspecting, modifying, and repairing the inner layers. In addition, in general, the cost of a single-sided board or of a double-sided board without vias is lower than the cost of a double-sided board with vias and lower than the cost of a multi-layer board. Thus on the one hand, single-sided boards and double-sided boards without vias are preferred in order to reduce costs. On the other hand, double-sided boards with vias or multi-layer boards are needed for more complex circuits. Many PCB designers and manufacturers are liable to be faced with an unsatisfactory choice between simple circuits at a lower cost or more powerful, versatile complex circuits at a greater cost.

Therefore, what is needed is to provide a PCB that can be manufactured at a reduced cost but still have reliable complex circuits.

### SUMMARY OF THE INVENTION

An exemplary embodiment of the present invention provides an electronic device. The electronic device includes an electronic component, a first printed circuit board (PCB) and a second printed circuit board. The electronic component includes a first pin and a second pin. The first PCB and a second PCB, respectively including first conductor trace lines and second conductor trace lines for electrically connecting the first pin and the second pin. The first PCB is disposed above the second PCB, and is parallel with the second PCB. The first PCB is electrically connected to the second PCB via at least one of the first conductor trace lines and the second conductor trace lines. A surface area of the first PCB is smaller than that of the second PCB.

Other advantages and novel features will become more apparent from the following detailed description of preferred embodiments when taken in conjunction with the accompanying drawings, in which:

### BRIEF DESCRIPTION OF THE DRAWINGS

FIG. 1 is a schematic, side cross-sectional view of a PCB assembly of a first exemplary embodiment of the present invention;

FIG. 2 is a schematic, side cross-sectional view of a PCB assembly of a second exemplary embodiment of the present invention;

FIG. 3 is a schematic, side cross-sectional view of a PCB assembly of a third exemplary embodiment of the present invention;

FIG. 4 is a schematic, side cross-sectional view of a PCB assembly of a fourth exemplary embodiment of the present invention;

FIG. 5 is schematic, side cross-sectional view of a PCB assembly of a fifth exemplary embodiment of the present invention;

FIG. 6 is a schematic, side cross-sectional view of a PCB assembly of a sixth exemplary embodiment of the present invention;

FIG. 7 is a schematic, side cross-sectional view of an electronic device of an exemplary embodiment of the present invention; and

FIG. 8 is a schematic, side cross-sectional view of an electronic device of another exemplary embodiment of the present invention.

### DETAILED DESCRIPTION OF THE INVENTION

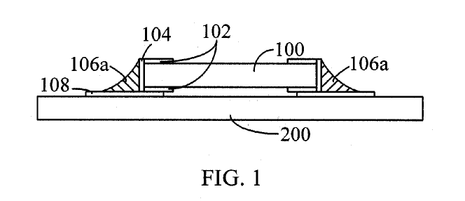

FIG. 1 is a schematic, side cross-sectional view of a printed circuit board (PCB) assembly of an electronic device shown as a first exemplary embodiment of the present invention. The PCB assembly comprises a first PCB 100 and a second PCB 200. The first PCB 100 is disposed above the second PCB 200, parallel with the second PCB 200. In the exemplary embodiment, the first PCB 100 is a double-sided board, and the second PCB 200 is a single-sided board. In addition, a surface area of the first PCB 100 is smaller than that of the second PCB 200. Furthermore, surface areas of the first PCB 100 and the second PCB 200 can be varied according to circuit design requirements. The second PCB 200 is typically used as a primary circuit board for a layout of electronic components.

The first PCB 100 comprises first conductor trace lines 102 disposed on a top surface and a bottom surface thereof, for providing electrical connections among a plurality of electronic components. The first conductor trace lines 102 are typically etched copper foils. In the exemplary embodiment, a plurality of vias (not shown) are embedded in the first PCB 100. Metal layers (not shown) are formed on inner walls of the vias, for electrically connecting the first conductor trace lines 102 disposed on the top surface of the first PCB 100 to the first conductor trace lines 102 disposed on the bottom surface of the first PCB 100.

The second PCB 200 comprises second conductor trace lines 108 disposed on a top surface thereof. In the exemplary embodiment, the second PCB 200 is electrically connected to the first PCB 100 via the first conductor trace lines 102 disposed on the bottom surface of the first PCB 100 and the second conductor trace lines 108 disposed on the top surface of the second PCB 200. The PCB assembly further comprises a plurality of solder portions 106a to electrically connect the first conductor trace lines 102 of the first PCB 100 and the second conductor trace lines 108 of the second PCB 200. In the exemplary embodiment, the first PCB 100 further comprises a plurality of metal layers 104 for connecting the first conductor trace lines 102 disposed on the top surface of the first PCB 100 to the first conductor trace lines 102 disposed on the bottom surface of the first PCB 100, and for providing joint points for the corresponding solder portions 106a. Each metal layer 104 is typically a thin metal film directly plated on the first PCB 100. Thus, both the metal layers 104 and the metal layers formed on the inner walls of the vias electrically connect the first conductor trace lines 102 disposed on the top surface of the first PCB 100 and the first conductor trace lines 102 disposed on the bottom surface of the first PCB 100.

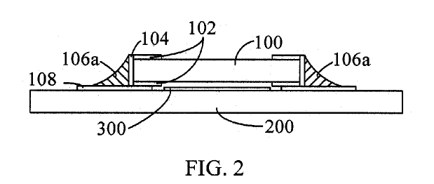

FIG. 2 is a schematic, side cross-sectional view of a PCB assembly of a second exemplary embodiment of the present invention. First conductor trace lines 102 of a first PCB 100 and second conductor trace lines 108 of a second PCB 200 in FIG. 2 have similar connections to those of FIG. 1. The difference is that the second PCB 200 further comprises an electromagnetic shield 300 disposed thereon. That is, the electromagnetic shield 300 is located directly under the first PCB 100, for protecting the first PCB 100 from electromagnetic interference. In this embodiment, the electromagnetic shield 300 is a copper foil.

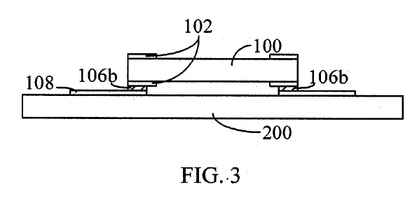

FIG. 3 is a schematic, side cross-sectional view of a PCB assembly of a third exemplary embodiment of the present invention. First conductor trace lines 102 of a first PCB 100 and second conductor trace lines 108 of a second PCB 200 in FIG. 3 have similar connections to those of FIG. 1. However, in this embodiment, some of the first conductor trace lines 102 of the first PCB 100 are electrically connected to the second conductor trace lines 108 of the second PCB 200 via solder portions 106b. In particular, the solder portions 106b are provided between first conductor trace lines 102 disposed on a bottom surface of the first PCB 100 and the second conductor trace lines 108 disposed on a top surface of the second PCB 200.

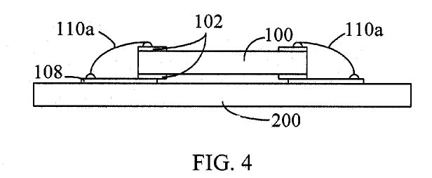

FIG. 4 is a schematic, side cross-sectional view of a PCB assembly of a fourth exemplary embodiment of the present invention. First conductor trace lines 102 of a first PCB 100 and second conductor trace lines 108 of a second PCB 200 in FIG. 4 have similar connections to those of FIG. 1. However, in this embodiment, some of the first conductor trace lines 102 of the first PCB 100 are electrically connected to the second conductor trace lines 108 of the second PCB 200 by a wire soldering process. In particular, solder wires 110a connect first conductor trace lines 102 disposed on a top surface of the first PCB 100 to the second conductor trace lines 108 disposed on a top surface of the second PCB 200.

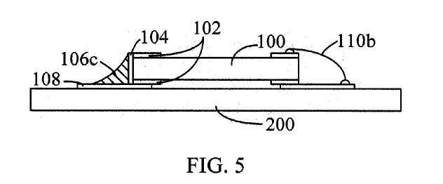

FIG. 5 is a schematic, side cross-sectional view of a PCB assembly of a fifth exemplary embodiment of the present invention. First conductor trace lines 102 of a first PCB 100 and second conductor trace lines 108 of a second PCB 200 in FIG. 5 have similar connections to those of FIG. 1. However, in this embodiment, at least one of the first conductor trace lines 102 of the first PCB 100 is electrically connected to at least one respective second conductor trace line 108 of the second PCB 200 by at least one solder portion 106c. At least another of the first conductor trace lines 102 of the first PCB 100 is electrically connected to at least another respective second conductor trace line 108 of the second PCB 200 by at least one solder wire 110b. In particular, the solder portion 106c and the solder wire 110b connect respective first conductor trace lines 102 disposed on a top surface of the first PCB 100 to corresponding second conductor trace lines 108 disposed on a top surface of the second PCB 200.

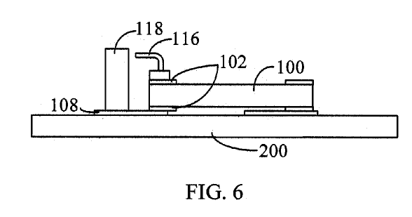

FIG. 6 is a schematic, side cross-sectional view of a PCB assembly of a sixth exemplary embodiment of the present invention. First conductor trace lines 102 of a first PCB 100 and second conductor trace lines 108 of a second PCB 200 in FIG. 5 have similar connections to those of FIG. 1. However, in this embodiment, at least one of the first conductor trace lines 102 of the first PCB 100 is electrically connected to at least one respective second conductor trace line 108 of the second PCB 200 by at least one connector. In particular, in the illustrated embodiment, the first PCB 100 comprises a first connector 116 connected to one of the first conductor trace lines 102 disposed on a top surface of the first PCB 100. The second PCB 200 comprises a second connector 118 connected to one of the second conductor trace lines 108 disposed on a top surface of the second PCB 200. In this embodiment, the first connector 116 is a male connector, and the second connector 118 is a female connector. Alternatively, the first connector 116 can be a female connector, and the second connector 118 can be a male connector. The first connector 116 is inserted into the second connector 118 in a direction parallel with the first PCB 100, and is thus engaged with the second connector 118. Thereby, the first conductor trace line 102 of the first PCB 100 is electrically connected to the second conductor trace line 108 of the second PCB 200.

In any of the above-described embodiments, preferably, complex or high voltage circuits are disposed on the first PCB 100, and other circuits are disposed on the second PCB 200. The first PCB 100 is typically a more expensive double-sided board with a smaller surface area. The second PCB 200 is typically a less expensive single-sided board that serves as the primary circuit board with a larger surface area. Thus overall, the PCB assembly can provide circuits with great complexity and high reliability at a relatively low cost.

In addition, in various alternative embodiments of any of the above-described first through sixth embodiments, the first PCB 100 can be a multi-layer board and is relatively thin. Hence, capacitors with either high capacitance or low capacitance can be formed and embedded in the PCB assembly.

In various further alternative embodiments of any of the above-described first through sixth embodiments and alternatives thereof, the second PCB 200 can be a double-sided board. Furthermore, means of connecting any of the first conductor trace lines 102 of the first PCB 100 and any of the second conductor trace lines 108 of the second PCB 200 can be any suitable one or combination of the means described above in relation to the first through sixth embodiments and alternatives thereof.

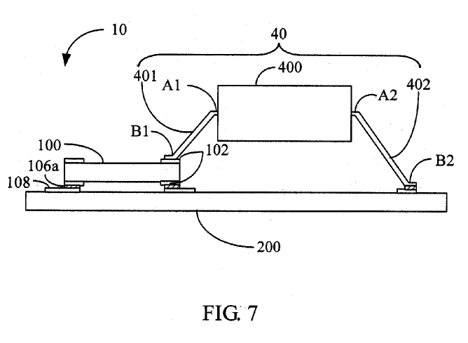

FIG. 7 is a schematic, side cross-sectional view of an electronic device 10 of an exemplary embodiment of the present invention. The electronic device 10 includes a first PCB 100, a second PCB 200 and an electronic component 40. The first PCB 100 is disposed above the second PCB 200, parallel with the second PCB 200. The first PCB 100 comprises first conductor trace lines 102 disposed on a top surface and a bottom surface thereof and the second PCB 200 comprises second conductor trace lines 108 disposed on a top surface thereof, for providing electrical connections among a plurality of electronic components. In the exemplary embodiment, the first PCB 100 is electrically connected to the second PCB 200 via solder portions 106a. In addition, a surface area of the first PCB 100 is smaller than that of the second PCB 200. In an alternative embodiment, the first PCB 100 and the second PCB 200 can be connected in other manners described in any of the above-described first through sixth embodiments.

In the exemplary embodiment, the electronic component 40, such as a transformer, or an inductor, includes a body 400, a first pin 401, and a second pin 402. The first pin 401 includes a first output end A1 and a first connecting end B1, and the second pin 402 includes a second output end A2 and a second connecting end B2. The first output end A1 and the second output end A2 are electrically connected to the body 400 of the electronic component 40 respectively. The first connecting end B1 is disposed on the top surface of the first PCB 100, and electrically connected to the first conductor trace lines 102. The second connecting end B2 is disposed on the top surface of the second PCB 200, and electrically connected to the second conductor trace lines 108. In the exemplary embodiment, the first output end A1 and the second output end A2 are disposed at the same height. Contrarily, the first connecting end B1 and the second connecting end B2 are disposed at different heights.

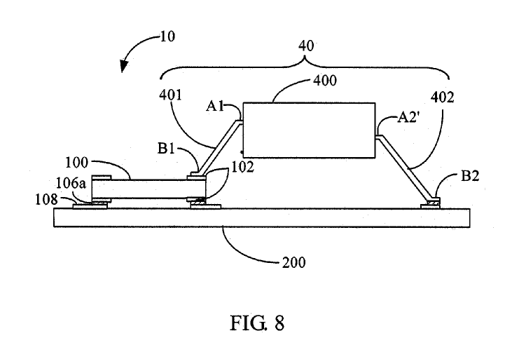

FIG. 8 is a schematic, side cross-sectional view of an electronic device 10 of another exemplary embodiment of the present invention. The electronic device 10 of FIG. 8 is the same as that of the FIG. 7, except that the first output end A1 and the second output end A2′ can be disposed at different heights.

While embodiments and methods of the present invention have been described above, it should be understood that they have been presented by way of example only and not by way of limitation. Thus the breadth and scope of the present invention should not be limited by the above-described exemplary embodiments, but should be defined only in accordance with the following claims and their equivalents.

What is claimed is:

1. A circuit board assembly, comprising:
two circuit boards;
wherein the circuit boards are parallel with and electrically connected to each other via at least one of conductor trace lines arranged thereon; and a surface area of one circuit board is smaller than that of the other circuit board.

2. The circuit board assembly as claimed in claim 1, wherein part of the conductor trace lines are arranged on at least two surfaces of one circuit board, and part of the conductor trace lines are arranged on a surface of the other circuit board.

3. The circuit board assembly as claimed in claim 1, further comprising a solder wire, which connects at least one of the conductor trace lines of one circuit board and at least one of the conductor traces lines of the other circuit board.

4. The circuit board assembly as claimed in claim 1, further comprising a solder portion, which connects at least one of the conductor trace lines of one circuit board and at least one of the conductor trace lines of the other circuit board.

5. The circuit board assembly as claimed in claim 2, wherein one circuit board further comprises a metal layer, which connects the conductor trace lines on the surfaces of one circuit board.

6. The circuit board assembly as claimed in claim 5, wherein the metal layer is a metal film directly plated on one circuit board.

7. The circuit board assembly as claimed in claim 5, wherein the metal layer is formed on an inner wall of a via of the one circuit board.

8. The circuit board assembly as claimed in claim 1, wherein one circuit board further comprises a connector electrically connected to at least one of the conductor trace lines of the one circuit board, and the other circuit board further comprises another connector electrically connected to at least one of the conductor trace lines of the other circuit board, and the another connector is engaged with and electrically connected to the connector.

9. The circuit board assembly as claimed in claim 8, wherein the connection of the connector and the other connector is parallel with the surface of the one circuit board.

10. The circuit board assembly as claimed in claim 1, wherein the other circuit board further comprises an electromagnetic shield disposed thereon under the one circuit board.

11. The circuit board assembly as claimed in claim 10, wherein the electromagnetic shield comprises a copper foil.

12. An electronic device, comprising:
an electronic component comprising a first pin and a second pin;
a first printed circuit board comprising first conductor trace lines being electrically connected to the first pin of the electronic component; and
a second printed circuit board comprising second conductor trace lines being electrically connected to the second pin of the electronic component;
wherein the first printed circuit board is disposed above the second printed circuit board, and is parallel with and electrically connected to the second printed circuit board via at least one of the first conductor trace lines and at least one of the second conductor trace lines;
and a surface area of the first printed circuit board is smaller than that of the second printed circuit board.

13. The electronic device as claimed in claim 12, wherein the first pin comprises a first connecting end and the second pin comprises a second connecting end; wherein the first connecting end is disposed on the first printed circuit board, and the second connecting end is disposed on the second printed circuit board.

14. The electronic device as claimed in claim 13, wherein the electronic component comprises a body, the first pin comprises a first output end and the second pin comprises a second output end; wherein the first output end and the second output end are electrically connected to the body respectively.

15. The electronic device as claimed in claim 14, wherein the first output end and the second output end are disposed at the same height.

16. The electronic device as claimed in claim 14, wherein the first output end and the second output end are disposed at different heights.

17. The electronic device as claimed in claim 13, wherein the first connecting end and the second connecting end are disposed at different heights.

18. The electronic device as claimed in claim 12, wherein the first conductor trace lines are disposed on at least two surfaces of the first printed circuit board, and the second conductor trace lines are disposed on a surface of the second printed circuit board.

19. An electronic device comprising:
a first circuit assembly occupying a first predefined surface and comprising first conductor trace lines arranged along said first surface;
a second circuit assembly occupying a second predefined surface defined beside said first surface in a parallel, side-by-side way, an occupying area of said second circuit assembly in said second surface sized larger than a projective area of said first circuit assembly at said second surface, said second circuit assembly comprising second conductor trace lines arranged along said second surface; and
an electronic component with a predetermined function arranged at a third surface other than said first and second surfaces, said electronic component comprising a first pin with a first connecting end extending toward said first surface so as to electrically connect with one of said first conductor trace lines, and a second pin with a second connecting end extending toward said second surface so as to electrically connect with one of said second conductor trace lines, an offset between said first connecting end and said second connecting end formed when said first connecting end electrically connects with said one of said first conductor trace lines, and said second connecting end electrically connects with said one of said second conductor trace lines, respectively.
